(19) United States
(12) Patent Application Publication
(10) Pub. No.: US 2025/0293214 A1
(43) Pub. Date: Sep. 18, 2025

(54) ELECTRONIC DEVICE

(71) Applicants: Kabushiki Kaisha Toshiba, Tokyo (JP); Toshiba Electronic Devices & Storage Corporation, Tokyo (JP)

(72) Inventor: Yutaka ONOZUKA, Yokohama Kanagawa (JP)

(21) Appl. No.: 19/056,650

(22) Filed: Feb. 18, 2025

(30) Foreign Application Priority Data
Mar. 18, 2024 (JP) 2024-042631
Mar. 18, 2024 (JP) 2024-042632

(51) Int. Cl. H01L 25/07; H01L 23/00; H01L 23/538

(52) U.S. Cl. CPC H01L 25/074; H01L 23/5386; H01L 24/09; H01L 2224/0903; H01L 2224/095; H01L 2225/06524

(57) ABSTRACT

A first connection part includes a first metal part electrically connected with a wiring layer, and a second metal part located on a second surface of a second substrate. The second metal part faces the first metal part in a first direction. A second connection part includes a third metal part electrically connected with the wiring layer, and a fourth metal part located on the second surface of the second substrate. The fourth metal part faces the third metal part in the first direction. One of the first connection part or the second connection part has a metal part-metal part bond structure. The other of the first connection part or the second connection part is capacitively coupled via a gap.

### CROSS-REFERENCE TO RELATED APPLICATION

This application is based upon and claims the benefit of priority from Japanese Patent Application No. 2024-042631, filed on Mar. 18, 2024, and Japanese Patent Application No. 2024-042632, filed on Mar. 18, 2024; the entire contents of which are incorporated herein by reference.

### FIELD

Embodiments described herein relate generally to an electronic device.

### BACKGROUND

A known device includes two chips bonded by a metal-to-metal bond.

### BRIEF DESCRIPTION OF THE DRAWINGS

FIG. 1 is a schematic cross-sectional view of an electronic device of a first embodiment;

FIG. 2 is a schematic plan view of an electronic device of a second embodiment;

FIG. 3 is an A-A cross-sectional view of FIG. 2;

FIG. 4 is a B-B cross-sectional view of FIG. 2;

FIG. 5 is a graph showing results of a simulation 1;

FIG. 6 is a graph showing results of a simulation 2;

FIG. 7 is a graph showing results of a simulation 3;

FIG. 8 is a schematic cross-sectional view of an electronic device of a third embodiment;

FIG. 9 is a schematic plan view of an electronic device of a fourth embodiment;

FIG. 10 is a C-C cross-sectional view of FIG. 9;

FIG. 11 is a D-D cross-sectional view of FIG. 9;

FIG. 12 is a graph showing results of a simulation 4; and

FIG. 13 is a graph showing results of a simulation 5.

### DETAILED DESCRIPTION

According to one embodiment, an electronic device includes a first substrate including a first surface; a second substrate including a second surface; a wiring part located at the first surface and positioned between the first surface and the second surface in a first direction, the wiring part including a wiring layer; a first connection part located on the wiring part, the first connection part including a first metal part electrically connected with the wiring layer, and a second metal part located on the second surface of the second substrate, the second metal part facing the first metal part in the first direction; and a second connection part located on the wiring part, the second connection part including a third metal part electrically connected with the wiring layer, and a fourth metal part located on the second surface of the second substrate, the fourth metal part facing the third metal part in the first direction, one of the first connection part or the second connection part having a metal part-metal part bond structure, the other of the first connection part or the second connection part being capacitively coupled via a gap.

According to one embodiment, an electronic device includes a first chip including a first substrate including a first surface, and a wiring part located at the first surface, the wiring part including a wiring layer; a second chip including a second substrate, the second substrate including a second surface facing the wiring part in a first direction; and a connection part located between the wiring part and the second surface, the connection part being electrically connected with the wiring layer, the connection part bonding the first chip and the second chip, the connection part including a first metal part and a second metal part facing each other in the first direction via a gap, and a first dielectric film located between the first metal part and the second metal part.

Exemplary embodiments will now be described with reference to the drawings.

The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a drawing thereinabove are marked with like reference numerals, and a detailed description is omitted as appropriate.

### First Embodiment

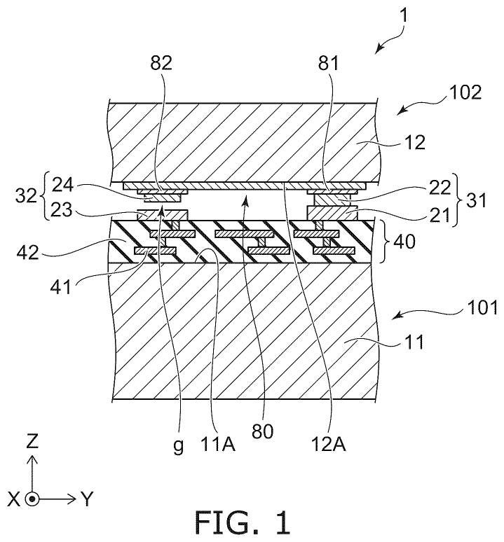

As shown in FIG. 1, an electronic device 1 of a first embodiment includes a first chip 101, a second chip 102, a first connection part 31, and a second connection part 32. The first chip 101 and the second chip 102 are stacked in a first direction Z and bonded via one connection part (in the example shown in FIG. 1, the first connection part 31) among the first connection part 31 and the second connection part 32. Two directions orthogonal to the first direction Z are taken as a second direction X and a third direction Y. The second direction X and the third direction Y are orthogonal to each other.

The first chip 101 includes a first substrate 11 and a wiring part 40. The first substrate 11 includes a first surface 11A. The first substrate 11 is, for example, a silicon substrate.

The wiring part 40 is located at the first surface 11A. The wiring part 40 includes an insulating layer 42, and a wiring layer 41 located inside the insulating layer 42. The wiring part 40 has, for example, a multilayer wiring structure in which the wiring layers 41 of different layers are electrically connected to each other by conductive vias.

The second chip 102 includes a second substrate 12 and an element part 80. The second substrate 12 includes a second surface 12A. The second substrate 12 is, for example, a silicon substrate. The wiring part 40 is positioned between the first surface 11A and the second surface 12A in the first direction Z.

The element part 80 is located at the second surface 12A. The element part 80 is positioned between the wiring part 40 and the second surface 12A in the first direction Z. The element part 80 includes a first electrode 81 and a second electrode 82. The element part 80 includes, for example, an n-type semiconductor layer, a p-type semiconductor layer, etc., located at the second surface 12A side and functions as a diode, a transistor, a light-emitting element, a light-receiving element, etc. Mutually different potentials are applied to the first and second electrodes 81 and 82.

The first connection part 31 includes a first metal part 21 and a second metal part 22. The first metal part 21 is located on the wiring part 40 and is electrically connected with the wiring layer 41 by a conductive via. The second metal part 22 is located on the second surface 12A of the second substrate 12 and faces the first metal part 21 in the first direction Z. The second metal part 22 contacts the first electrode 81 of the second chip 102 and is electrically connected with the first electrode 81.

The second connection part 32 includes a third metal part 23 and a fourth metal part 24. The third metal part 23 is located on the wiring part 40 and is electrically connected with the wiring layer 41 by a conductive via. The fourth metal part 24 is located on the second surface 12A of the second substrate 12 and faces the third metal part 23 in the first direction Z. The fourth metal part 24 contacts the second electrode 82 of the second chip 102 and is electrically connected with the second electrode 82.

The first metal part 21 and the third metal part 23 are arranged to be separated from each other on the wiring part 40. Mutually different potentials are applied to the first and third metal parts 21 and 23 via the wiring layer 41. For example, a positive potential is applied to the first metal part 21; and a ground potential (0 V) is applied to the third metal part 23. One connection part among the first connection part 31 and the second connection part 32 has a metal part-metal part bond structure; and the other connection part among the first connection part 31 and the second connection part 32 is capacitively coupled via a gap g. In the example shown in FIG. 1, the first connection part 31 has a bond structure between the first metal part 21 and the second metal part 22; and the second connection part 32 is capacitively coupled via the gap g.

For example, the metal parts of the first and second connection parts 31 and 32 are made of gold. The bond structure between the first metal part 21 and the second metal part 22 has a gold-gold bond structure. The third metal part 23 and the fourth metal part 24 face each other in the first direction Z with the gap g interposed. The gap g is an air gap.

The first chip 101 is a control chip that controls the element part 80. A control circuit that includes semiconductor transistors and the like is formed at the first surface 11A side of the first substrate 11; and the control circuit is electrically connected with the wiring layer 41. The first electrode 81 of the element part 80 is electrically connected with the wiring layer 41 via the first connection part 31 in which the metal parts are directly bonded to each other. The second electrode 82 of the element part 80 is electrically connected with the wiring layer 41 via the capacitive coupling of the second connection part 32. For example, the ground potential is applied to the first and second substrates 11 and 12.

For example, multiple element parts 80 are located on the second surface 12A of the second substrate 12. Accordingly, multiple first connection parts 31 and multiple second connection parts 32 are located between the first chip 101 and the second chip 102.

The first metal part 21 and the second metal part 22 are directly bonded by causing the first metal part 21 and the second metal part 22 to contact each other, by applying a load in the first direction Z to the first and second metal parts 21 and 22, and by heating. The metal part-metal part contact area is increased by increasing number of the metal part-metal part bonding locations. If the load that is applied by the bonding apparatus is limited, the load may be insufficient for bonding when the metal part-metal part contact area is increased, and bonding defects easily occur. 35

According to the embodiment, for example, at the second connection part 32, the metal parts are not bonded to each other, and the metal parts are capacitively coupled via the gap g. As a result, the number of metal part-metal part bonding locations between the first chip 101 and the second chip 102 can be reduced, a sufficient load can be applied to the bonding parts (the first connection parts 31), and bonding defects can be reduced.

A voltage that is reduced by the partial voltage across the capacitance of the second connection part 32 is applied to the second electrode 82. Therefore, the second electrode 82 tends to be difficult to control to have the desired potential (in the example, the ground potential). By optimizing the capacitance value of the second connection part 32, the appropriate voltage can be applied between the first electrode 81 and the second electrode 82. According to the embodiment, there are cases where the ground potential is applied to the second substrate 12; and the potential of the second electrode 82 is easily set to the ground potential. From such a perspective, among the first connection part 31 and the second connection part 32, it is favorable for the connection part that is capacitively coupled to be the second connection part 32 to which the ground potential is applied. As described below, it is favorable for the size in the first direction Z of the gap g between the third metal part 23 and the fourth metal part 24 to be not more than 3 μm.

### Second Embodiment

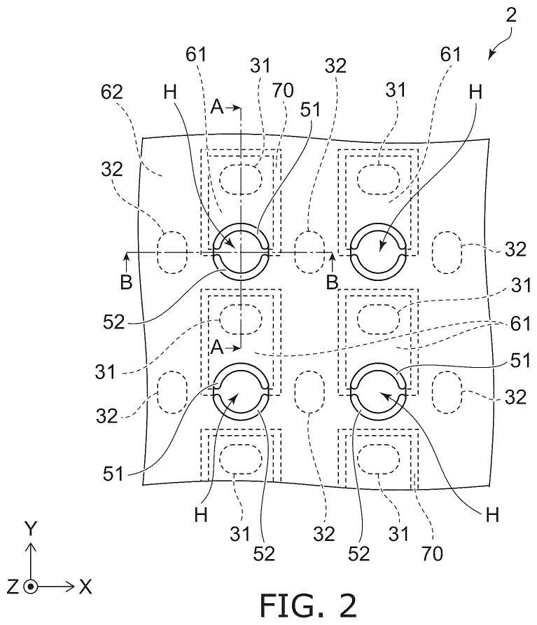

FIG. 2 is a schematic plan view of an electronic device 2 of a second embodiment.

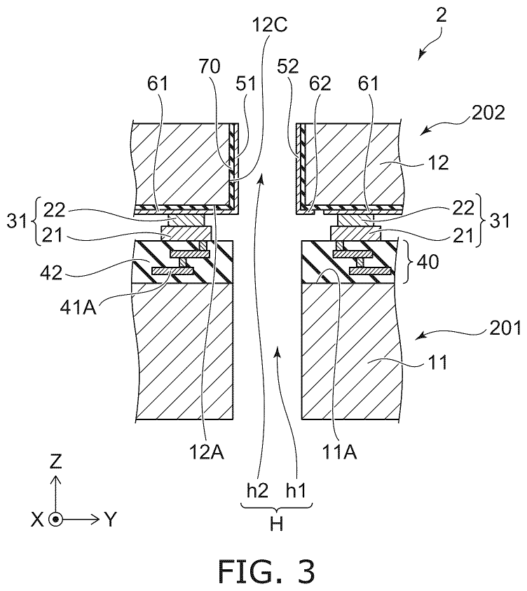

FIG. 3 is an A-A cross-sectional view of FIG. 2. FIG. 3 illustrates a cross section of a part where the first connection part 31, in which the metal parts are bonded to each other, is located.

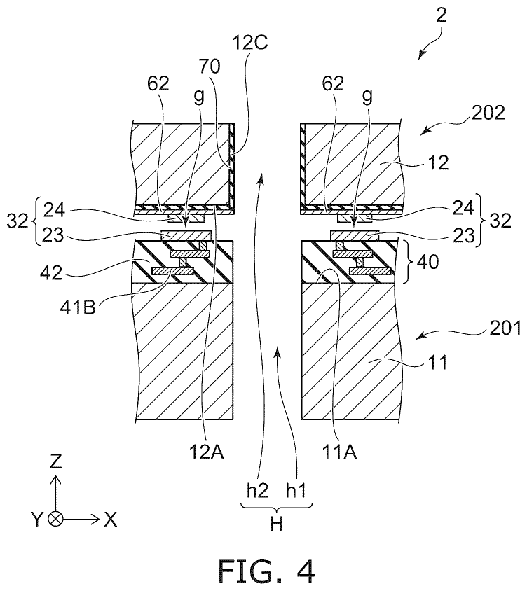

FIG. 4 is a B-B cross-sectional view of FIG. 2. FIG. 4 illustrates a cross section of a part where the second connection part 32, which is capacitively coupled, is located.

The electronic device 2 of the second embodiment includes a first chip 201, a second chip 202, the first connection part 31, and the second connection part 32. The first chip 201 and the second chip 202 are stacked in the first direction Z and bonded via one (according to the embodiment, the first connection part 31) of the first connection part 31 or the second connection part 32.

The first chip 201 includes the first substrate 11 and the wiring part 40. The first substrate 11 includes the first surface 11A. The first substrate 11 is, for example, a silicon substrate. The first chip 201 includes a first through-part h1 that extends through the first substrate 11 and the wiring part 40 in the first direction Z.

The wiring part 40 is located at the first surface 11A. The wiring part 40 includes the insulating layer 42, and a wiring layer located inside the insulating layer 42. The wiring layer includes a first wiring layer 41A and a second wiring layer 41B. The wiring part 40 is, for example, a multilayer wiring structure in which wiring layers of different layers are electrically connected to each other by conductive vias.

The second chip 202 includes the second substrate 12, a first electrode 51, and a second electrode 52. The second substrate 12 includes the second surface 12A. The second substrate 12 is, for example, a silicon substrate. The wiring part 40 is positioned between the first surface 11A and the second surface 12A in the first direction Z. The second chip 202 includes a second through-part h2 that extends through the second substrate 12 in the first direction Z. The first through-part h1 of the first chip 201 and the second through-part h2 of the second chip 202 are arranged in the first direction Z and are included in a through-hole H of the electronic device 2. The through-hole H extends through the second substrate 12, the wiring part 40, and the first substrate 11 in the first direction Z. For example, the ground potential is applied to the first and second substrates 11 and 12.

A first conductive film 61 and a second conductive film 62 are located at the second surface 12A of the second substrate 12 with an insulating film 70 interposed. The first electrode 51 and the second electrode 52 are located at an inner side surface 12C of the second through-part h2 with the insulating film 70 interposed. The insulating film 70 is, for example, a silicon oxide film. The insulating film 70 is located between the second surface 12A and the first conductive film 61, between the second surface 12A and the second conductive film 62, between the inner side surface 12C and the first electrode 51, and between the inner side surface 12C and the second electrode 52. The insulating film 70 may not be included when the second substrate 12 is insulative.

As shown in FIG. 2, the first electrode 51 and the second electrode 52 are separated from each other in the circumferential direction of the inner side surface 12C at the inner side surface 12C of the second through-part h2. The first conductive film 61 and the second conductive film 62 are separated from each other by the insulating film 70 on the second surface 12A. The first electrode 51 is electrically connected with the first conductive film 61. The second electrode 52 is electrically connected with the second conductive film 62. Mutually different potentials are applied to the first and second electrodes 51 and 52.

As shown in FIG. 3, the first connection part 31 includes the first metal part 21 and the second metal part 22. The first metal part 21 is located on the wiring part 40 and is electrically connected with the first wiring layer 41A by a conductive via. The second metal part 22 is located in contact with the first conductive film 61 on the second surface 12A of the second substrate 12 and faces the first metal part 21 in the first direction Z. The second metal part 22 is electrically connected with the first electrode 51 via the first conductive film 61.

As shown in FIG. 4, the second connection part 32 includes the third metal part 23 and the fourth metal part 24. The third metal part 23 is located on the wiring part 40 and is electrically connected with the second wiring layer 41B by a conductive via. The fourth metal part 24 is located in contact with the second conductive film 62 on the second surface 12A of the second substrate 12 and faces the third metal part 23 in the first direction Z. The fourth metal part 24 is electrically connected with the second electrode 52 (shown in FIG. 3) via the second conductive film 62.

The first metal part 21 and the third metal part 23 are arranged to be separated from each other on the wiring part 40. Mutually different potentials are applied to the first and third metal parts 21 and 23 via the first and second wiring layers 41A and 41B. For example, a positive potential is applied to the first metal part 21; and the ground potential is applied to the third metal part 23.

One connection part among the first connection part 31 and the second connection part 32 has a metal part-metal part bond structure; and the other connection part among the first connection part 31 and the second connection part 32 is capacitively coupled via the gap g. According to the embodiment, the first connection part 31 has the bond structure between the first metal part 21 and the second metal part 22; and the second connection part 32 is capacitively coupled via the gap g.

For example, the metal parts of the first and second connection parts 31 and 32 are made of gold. The bond structure between the first metal part 21 and the second metal part 22 has a gold-gold bond structure. The third metal part 23 and the fourth metal part 24 face each other in the first direction Z with the gap g interposed. The gap g is an air gap.

As shown in FIG. 2, the electronic device 2 includes the multiple through-holes H, the multiple first connection parts 31, and the multiple second connection parts 32. The multiple through-holes H are arranged in the second and third directions X and Y. The first conductive films 61 are arranged to have a one-to-one correspondence with the through-holes H. The first connection parts 31 are arranged in contact with the first conductive films 61 to have a one-to-one correspondence with the through-holes H. One through-hole H is positioned between the first connection parts 31 that are adjacent to each other in the third direction Y. One through-hole H is positioned between the second connection parts 32 that are adjacent to each other in the second direction X. Two second connection parts 32 are provided for one through-hole H with the through-hole H interposed in the second direction X. The number of the second connection parts 32 is greater than the number of the first connection parts 31. The potentials of the multiple second electrodes 52 can be collectively controlled via the multiple second connection parts 32 and the common second conductive film 62. The potentials of the multiple first electrodes 51 each are individually controlled via the corresponding first connection part 31 and the corresponding first conductive film 61.

The electronic device 2 of the second embodiment can be used as a pixel array that deflects electron beams of a multi-electron beam lithography apparatus that uses multiple electron beams to draw a pattern in a resist on a substrate of glass, etc. The electron beam passes through the through-hole H. The electron beam that passes through the through-hole H can be deflected by the electric field generated between the first electrode 51 and the second electrode 52.

By bonding two chips (the first chip 201 and the second chip 202) that each have through-holes, the electronic device 2 that has a deep through-hole that would be difficult to form in a solitary chip can be configured.

In the electronic device 2, the first metal part 21 and the second metal part 22 are directly bonded by causing the first metal part 21 and the second metal part 22 to contact each other, by applying a load in the first direction Z to the first and second metal parts 21 and 22, and by heating. Due to the trend of increasing the number of pixels which increases the number of the through-holes H of multi-electron beam lithography apparatuses, there is a tendency for the number of connection parts also to increase, and for the metal part-metal part contact area to increase.

According to the embodiment, for example, the second connection part 32 is capacitively coupled via the gap g without bonding the metal parts to each other. As a result, the metal part-metal part bonding locations between the first chip 201 and the second chip 202 can be reduced, a sufficient load can be applied to the bonding parts (the first connection parts 31), and bonding defects can be reduced.

A voltage that is reduced by the partial voltage across the capacitance of the second connection part 32 is applied to the second electrode 52. Therefore, the second electrode 52 has a tendency to be difficult to control to have the desired potential (in the example, the ground potential). By optimizing the capacitance value of the second connection part 32, an appropriate voltage can be applied between the first electrode 51 and the second electrode 52. According to the embodiment, there are cases where the ground potential is applied to the second substrate 12, and the potential of the second electrode 52 is easily set to the ground potential. From such a perspective, it is favorable for the connection part among the first connection part 31 and the second connection part 32 that is capacitively coupled to be the second connection part 32 to which the ground potential is applied.

### Simulation 1

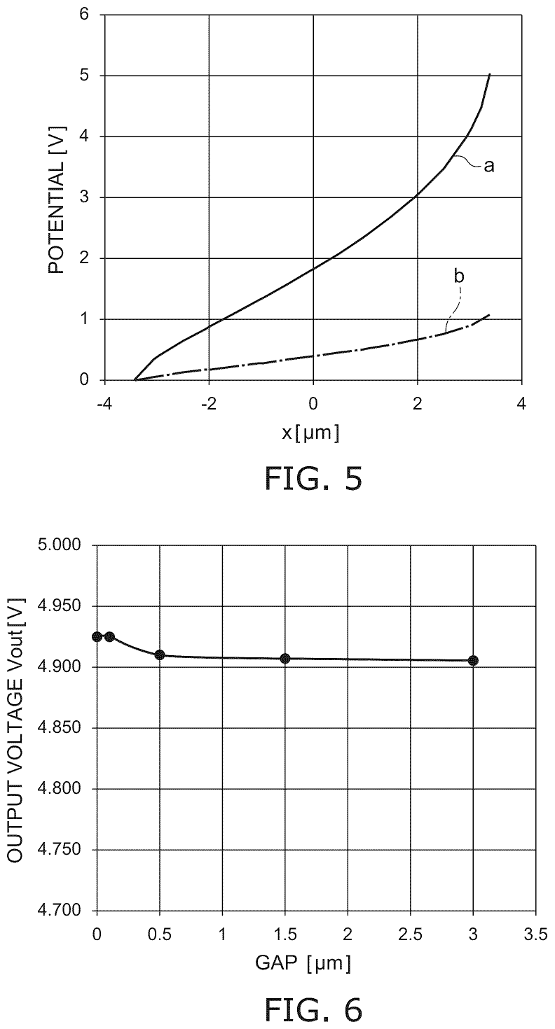

The potential was calculated by simulation for a model of a cross-sectional structure in which the first electrode 51 and the second electrode 52 faced each other with the through-hole H interposed, 5 V was applied to the first metal part 21, and 0 V was applied to the third metal part 23. The results are shown in FIG. 5.

In the horizontal axis of FIG. 5, x=0 represents a position of 3 μm from the first electrode 51 toward the second electrode 52. The inner side surface of the first electrode 51 at the second electrode 52 side is at a position of x=3 μm; and the inner side surface of the second electrode 52 at the first electrode 51 side is at a position of x=−3 μm. The position of x=0 matches the central axis of the through-hole H. The model a illustrates the result when 0 V was applied to the second connection part 32, the second connection part 32 was capacitively coupled via the gap g, 5 V was applied to the first connection part 31, and the first connection part 31 had a metal part-metal part bond structure. In contrast, the model b illustrates the result when 0 V was applied to the second connection part 32, the second connection part 32 had a metal part-metal part bond structure, 5 V was applied to the first connection part 31, and the first connection part 31 was capacitively coupled via the gap g. The size (the size in the first direction Z) of the gap g was set to 0.1 μm. 0 V was applied to the first and second substrates 11 and 12.

A simulation of the case (a comparative example 1) where both the first and second connection parts 31 and 32 had metal part-metal part bond structures substantially matched the graph of a. It can be seen from this result that even when the second connection part 32 at the 0 V side had a capacitively-coupled structure, the electric field that was generated inside the through-hole H was equivalent to that of a metal part-metal part bond structure. It may be considered that this was affected by the large capacitance between the first substrate 11 and the second substrate 12 causing the second electrode 52 to be in a substantially grounded state. On the other hand, as shown in the graph of b, the potential at the position of x=0 was low and was about ⅕ of those of the graph of a and the comparative example 1 in which 5 V was applied to the first connection part 31 side and the first connection part 31 side had the capacitively-coupled structure.

### Simulation 2

FIG. 6 shows simulation results of the gap dependence of the output voltage for the model described above, in which 0 V was applied to the second connection part 32, the second connection part 32 was capacitively coupled via the gap g, 5 V was applied to the first connection part 31, and the first connection part 31 had a metal part-metal part bond structure. The horizontal axis is the size of the gap g, and the vertical axis is an output voltage Vout. Other than the size of the gap g, the conditions were the same as those of the simulation 1 described above.

Based on the results of FIG. 6, the reduction of the output voltage Vout when the size of the gap g was not more than 3 μm was suppressed to be within about 0.4% of the output voltage Vout when the gap was 0.

### Simulation 3

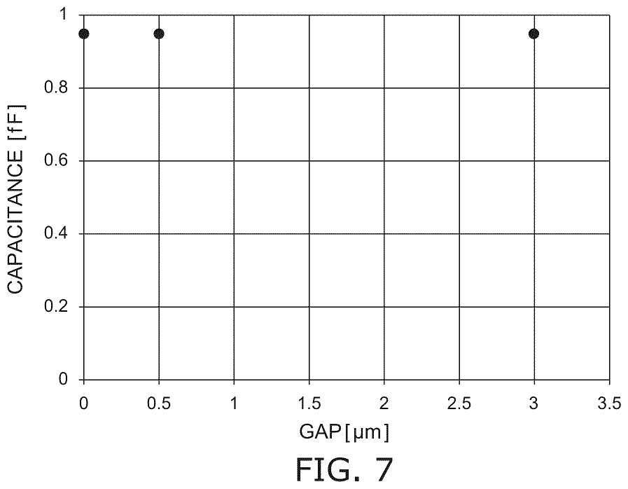

The time constant when writing 5 V to the first electrode 51 (a deflection electrode) was estimated for a model having conditions similar to those of the simulation 2. The time constant is the product of the wiring resistance and the load capacitance; and it is considered that for equal wiring resistances, the time constant is determined by the magnitude of the load capacitance. It can be seen from the results of FIG. 7 that the load capacitance was constant regardless of the size of the gap g (including 0); and the write time to the deflecting electrode was not increased by the gap g.

### Third Embodiment

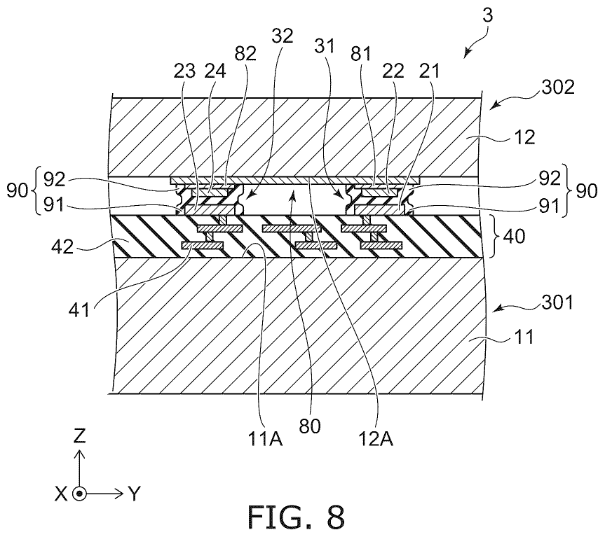

As shown in FIG. 8, an electronic device 3 of a third embodiment includes a first chip 301, a second chip 302, the first connection part 31, and the second connection part 32. The first connection part 31 and the second connection part 32 are located between the first chip 301 and the second chip 302. The first chip 301 and the second chip 302 are stacked in the first direction Z and bonded to each other via the first and second connection parts 31 and 32.

The first chip 301 includes the first substrate 11 and the wiring part 40. The second chip 302 includes the second substrate 12 and the element part 80.

The first connection part 31 and the second connection part 32 are located between the wiring part 40 and the second surface 12A and electrically connected with the wiring layer 41.

The first connection part 31 includes the first metal part 21 and the second metal part 22. The first metal part 21 is located on the wiring part 40 and electrically connected with the wiring layer 41 by a conductive via. The second metal part 22 contacts the first electrode 81 of the second chip 302 and is electrically connected with the first electrode 81. The first metal part 21 and the second metal part 22 face each other in the first direction Z with a gap interposed.

The second connection part 32 includes the third metal part 23 and the fourth metal part 24. The third metal part 23 is located on the wiring part 40 and is electrically connected with the wiring layer 41 by a conductive via. The fourth metal part 24 contacts the second electrode 82 of the second chip 302 and is electrically connected with the second electrode 82. The third metal part 23 and the fourth metal part 24 face each other in the first direction Z with a gap interposed.

For example, gold can be used as a material of the first to fourth metal parts 21 to 24. The first metal part 21 and the third metal part 23 are arranged to be separated from each other on the wiring part 40. Mutually-different potentials are applied to the first and third metal parts 21 and 23 via the wiring layer 41. For example, a positive potential is applied to the first metal part 21; and the ground potential (0 V) is applied to the third metal part 23.

The first connection part 31 further includes a dielectric film (a first dielectric film) 90 located between the first metal part 21 and the second metal part 22. The first metal part 21 and the second metal part 22 are capacitively coupled via the dielectric film 90.

The second connection part 32 further includes the dielectric film (the second dielectric film) 90 located between the third metal part 23 and the fourth metal part 24. According to the embodiment, for example, the first dielectric film and the second dielectric film are made of the same material and are marked with the same reference numeral 90. The third metal part 23 and the fourth metal part 24 are capacitively coupled via the dielectric film 90.

For example, a first dielectric film 91 is formed to cover the first metal part 21 and the third metal part 23 on the wiring part 40; and a second dielectric film 92 is formed to cover the second metal part 22 and the fourth metal part 24 on the second surface 12A. After forming the first dielectric film 91 and the second dielectric film 92, the first dielectric film 91 and the second dielectric film 92 are bonded by causing the first dielectric film 91 and the second dielectric film 92 to contact each other, by applying a load to the first and second dielectric films 91 and 92 in the first direction Z, and by heating as necessary. The first chip 301 and the second chip 302 are bonded to each other by the dielectric film 90 that is joined as a continuous body by the bond between the first dielectric film 91 and the second dielectric film 92. Examples of the material of the dielectric film 90 and the bonding method are described below.

The first chip 301 is a control chip that controls the element part 80. A control circuit that includes semiconductor transistors and the like is formed in the first surface 11A side of the first substrate 11; and the control circuit is electrically connected with the wiring layer 41. The first electrode 81 of the element part 80 is electrically connected with the wiring layer 41 via the first connection part 31 having a capacitively-coupled structure. The second electrode 82 of the element part 80 is electrically connected with the wiring layer 41 via the second connection part 32 having a capacitively-coupled structure. For example, the ground potential is applied to the first and second substrates 11 and 12.

For example, multiple element parts 80 are located on the second surface 12A of the second substrate 12. Accordingly, multiple first connection parts 31 and multiple second connection parts 32 are located between the first chip 301 and the second chip 302.

It may be considered, as a comparative example 2, to bond the first chip 301 and the second chip 302 by using the first connection part 31 and the second connection part 32 that have metal part-metal part bond structures. In such a case, the first metal part 21 and the second metal part 22 are directly bonded and the third metal part 23 and the fourth metal part 24 are directly bonded by causing the first metal part 21 and the second metal part 22 to contact each other, by causing the third metal part 23 and the fourth metal part 24 to contact each other, by applying a load to the metal parts in the first direction Z, and by heating. The metal part-metal part contact area increases as the number of metal part-metal part bonding locations increases. When the load that can be applied by the bonding apparatus is limited, the load becomes insufficient for bonding when the metal part-metal part contact area is increased, and bonding defects easily occur.

According to the embodiment, the metal parts are not bonded to each other for the first and second connection parts 31 and 32; and the first chip 301 and the second chip 302 are bonded by the dielectric film 90 located between the metal parts facing each other in the first direction Z. When metal parts are used for the electrical connection between the first chip 301 and the second chip 302, the materials for the metal parts are constrained, whereas materials that can be bonded by a low load can be selected as the material of the dielectric film 90. As a result, a sufficient load can be applied to the first and second connection parts 31 and 32; and bonding defects can be reduced.

It is possible to bond a first wafer including the configuration of the first chip 301 and a second wafer including the configuration of the second chip 302 at the wafer level via the dielectric film 90, and to singulate the electronic devices 3. As a result, the throughput can be improved, and the cost of the electronic device 3 can be reduced.

A voltage that is reduced by the partial voltage across the capacitances of the connection parts 31 and 32 is applied between the first electrode 81 and the second electrode 82. An appropriate voltage can be applied between the first electrode 81 and the second electrode 82 by optimizing the capacitance value by adjusting the thickness (the thickness in the first direction Z) of the dielectric film 90 and/or the relative dielectric constant of the connection parts 31 and 32, etc.

### Fourth Embodiment

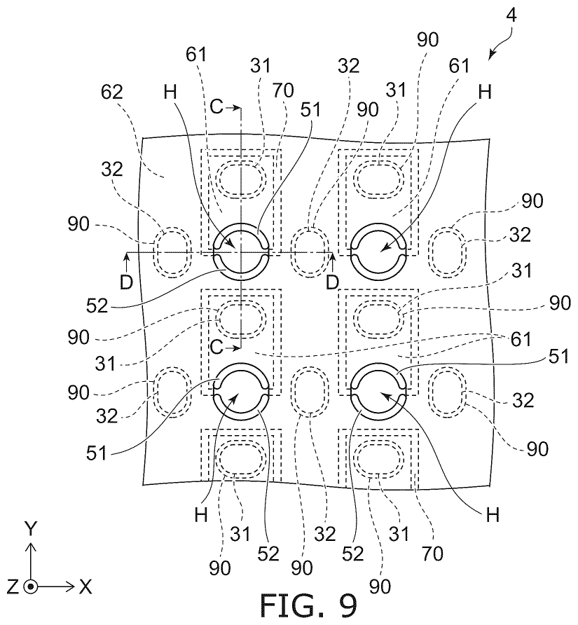

FIG. 9 is a schematic plan view of an electronic device 4 of a fourth embodiment.

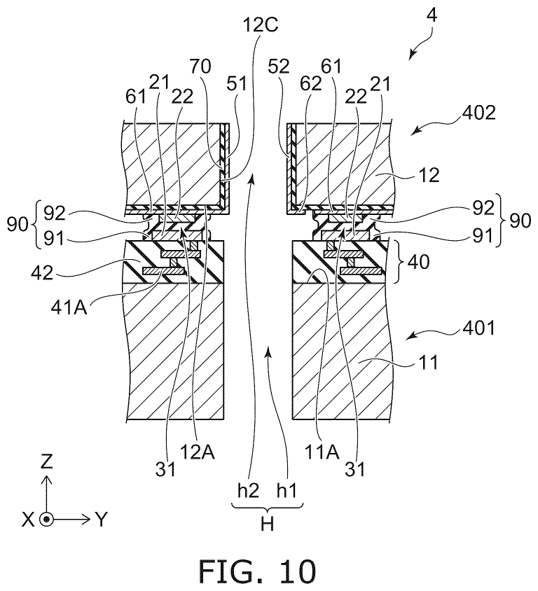

FIG. 10 is a C-C cross-sectional view of FIG. 9. FIG. 10 illustrates a cross section of a part where the first connection part 31 is located.

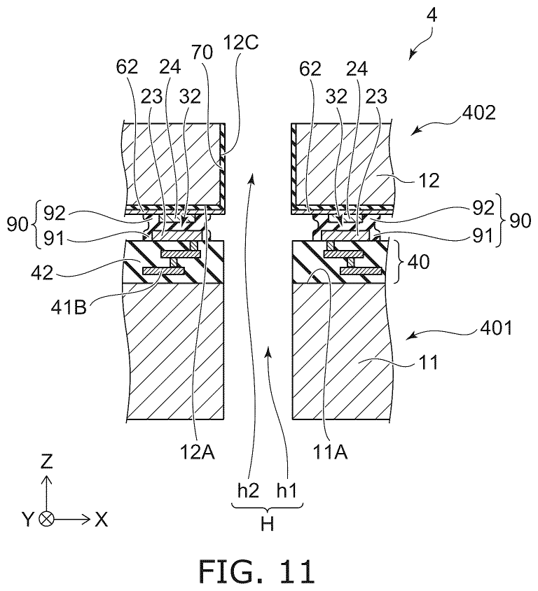

FIG. 11 is a D-D cross-sectional view of FIG. 9. FIG. 11 illustrates a cross section of a part where the second connection part 32 is located.

The electronic device 4 of the fourth embodiment includes a first chip 401, a second chip 402, the first connection part 31, and the second connection part 32. The first connection part 31 and the second connection part 32 are located between the first chip 401 and the second chip 402. The first chip 401 and the second chip 402 are stacked in the first direction Z and bonded to each other via the first and second connection parts 31 and 32.

The first chip 401 includes the first substrate 11 and the wiring part 40. The first chip 401 includes the first through-part h1 that extends through the first substrate 11 and the wiring part 40 in the first direction Z.

The second chip 402 includes the second substrate 12, the first electrode 51, and the second electrode 52. The second chip 402 includes the second through-part h2 that extends through the second substrate 12 in the first direction Z. The first through-part h1 of the first chip 401 and the second through-part h2 of the second chip 402 are arranged in the first direction Z and are included in the through-hole H of the electronic device 4. The through-hole H extends through the second substrate 12, the wiring part 40, and the first substrate 11 in the first direction Z. For example, the ground potential is applied to the first and second substrates 11 and 12.

As shown in FIG. 10, the first connection part 31 is located between the wiring part 40 and the second surface 12A and includes the first metal part 21 and the second metal part 22. The first metal part 21 is located on the wiring part 40 and electrically connected with the first wiring layer 41A by a conductive via. The second metal part 22 contacts the first conductive film 61 and is electrically connected with the first conductive film 61. The second metal part 22 is electrically connected with the first electrode 51 via the first conductive film 61. The first metal part 21 and the second metal part 22 face each other in the first direction Z with a gap interposed.

As shown in FIG. 11, the second connection part 32 is located between the wiring part 40 and the second surface 12A and includes the third metal part 23 and the fourth metal part 24. The third metal part 23 is located on the wiring part 40 and electrically connected with the second wiring layer 41B by a conductive via. The fourth metal part 24 contacts the second conductive film 62 and is electrically connected with the second conductive film 62. The fourth metal part 24 is electrically connected with the second electrode 52 via the second conductive film 62. The third metal part 23 and the fourth metal part 24 face each other in the first direction Z with a gap interposed.

Mutually-different potentials are applied to the first and third metal parts 21 and 23. For example, a positive potential is applied to the first metal part 21 via the first wiring layer 41A; and the ground potential is applied to the third metal part 23 via the second wiring layer 41B.

The first connection part 31 further includes the dielectric film 90 located between the first metal part 21 and the second metal part 22. The first metal part 21 and the second metal part 22 are capacitively coupled via the dielectric film 90.

The second connection part 32 further includes the dielectric film 90 located between the third metal part 23 and the fourth metal part 24. The third metal part 23 and the fourth metal part 24 are capacitively coupled via the dielectric film 90.

For example, the first dielectric film 91 is formed to cover the first metal part 21 and the third metal part 23 on the wiring part 40; and the second dielectric film 92 is formed to cover the second metal part 22 and the fourth metal part 24 on the second surface 12A. After forming the first dielectric film 91 and the second dielectric film 92, the first dielectric film 91 and the second dielectric film 92 are bonded by causing the first dielectric film 91 and the second dielectric film 92 to contact each other, by applying a load to the first and second dielectric films 91 and 92 in the first direction Z, and by heating as necessary. The first chip 401 and the second chip 402 are bonded to each other by the dielectric film 90 that is joined as a continuous body by the bond between the first dielectric film 91 and the second dielectric film 92.

As shown in FIG. 9, the electronic device 4 includes the multiple through-holes H, the multiple first connection parts 31, and the multiple second connection parts 32. The multiple through-holes H are arranged in the second and third directions X and Y. The first conductive films 61 are arranged to have a one-to-one correspondence with the through-holes H. The first connection parts 31 are arranged in contact with the first conductive films 61 to have a one-to-one correspondence with the through-holes H. One through-hole H is positioned between the first connection parts 31 that are adjacent to each other in the third direction Y. One through-hole H is positioned between the second connection parts 32 that are adjacent to each other in the second direction X. Two second connection parts 32 are provided for one through-hole H with the through-hole H interposed in the second direction X. The number of the second connection parts 32 is greater than the number of the first connection parts 31. The potentials of the multiple second electrodes 52 can be collectively controlled via the multiple second connection parts 32 and the common second conductive film 62. The potentials of the multiple first electrodes 51 each are individually controlled via the corresponding first connection part 31 and the corresponding first conductive film 61.

The electronic device 4 of the fourth embodiment can be used as a pixel array that deflects electron beams of a multi-electron beam lithography apparatus that uses multiple electron beams to draw a pattern in a resist on a substrate of glass, etc. The electron beam passes through the through-hole H. The electron beam that passes through the through-hole H can be deflected by the electric field generated between the first electrode 51 and the second electrode 52.

By bonding two chips (the first chip 401 and the second chip 402) that each have through-holes, the electronic device 2 that has a deep through-hole that would be difficult to form in a solitary chip can be configured.

Due to the trend of increasing the number of pixels which increases the number of the through-holes H of multi-electron beam lithography apparatuses, there is a tendency for the number of connection parts also to increase, and for the metal part-metal part contact area to increase.

According to the embodiment, the metal parts are not bonded to each other for the first and second connection parts 31 and 32; and the first chip 401 and the second chip 402 are bonded by the dielectric film 90 located between the metal parts facing each other in the first direction Z. When metal parts are used for the electrical connection between the first chip 401 and the second chip 402, the materials for the metal parts are constrained, whereas materials that can be bonded by a low load can be selected as the material of the dielectric film 90. As a result, a sufficient load can be applied to the first and second connection parts 31 and 32; and bonding defects can be reduced.

It is possible to bond a first wafer including the configuration of the first chip 401 and a second wafer including the configuration of the second chip 402 at the wafer level via the dielectric film 90, and to singulate the electronic devices 4. As a result, the throughput can be improved, and the cost of the electronic device 4 can be reduced.

A voltage that is reduced by the partial voltage across the capacitances of the connection parts 31 and 32 is applied between the first electrode 51 and the second electrode 52. An appropriate voltage can be applied between the first electrode 51 and the second electrode 52 by optimizing the capacitance value by adjusting the thickness (the thickness in the first direction Z) of the dielectric film 90 and/or the relative dielectric constant of the connection parts 31 and 32, etc.

For example, a silicon oxide film or a silicon nitride film can be used as the dielectric film 90. A metal-oxide film can be used as the dielectric film 90. For example, an aluminum oxide film, a hafnium oxide film, a zirconium oxide film, a lanthanum oxide film, etc., can be used as the metal-oxide film.

The first dielectric film 91 is formed at the first chip 301 side and at the first chip 401 side; and the second dielectric film 92 is formed at the second chip 302 side and at the second chip 402 side. Subsequently, plasma processing using, for example, Ar is performed on the first and second dielectric films 91 and 92. The plasma processing removes contaminants at the surface and, for example, when Si is included, exposes Si dangling bonds at the surfaces of the films. Subsequently, the first dielectric film 91 and the second dielectric film 92 are caused to contact, a load is applied to the first and second dielectric films 91 and 92 in the first direction Z, and then the first dielectric film 91 and the second dielectric film 92 are heated. When Si is included, the first chips 301 and 401 and the second chips 302 and 402 are bonded by the first and second dielectric films 91 and 92 being bonded to form the dielectric film 90 by thermal compression bonding due to Si—Si bonds.

### Simulation 4

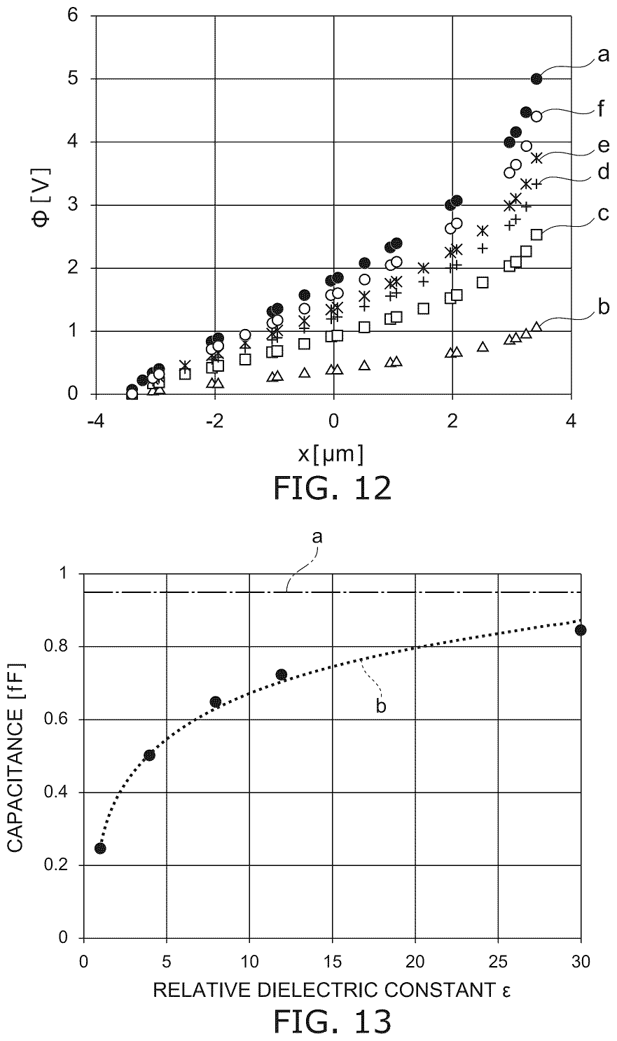

A potential ϕ was calculated by simulation for a model of a cross-sectional structure in which the first electrode 51 and the second electrode 52 faced each other with the through-hole H interposed, 5 V was applied to the first metal part 21, and 0 V was applied to the third metal part 23, the first substrate 11, and the second substrate 12. The results are shown in FIG. 12.

In the horizontal axis of FIG. 12, x=0 represents a position of 3 μm from the first electrode 51 toward the second electrode 52. The inner side surface of the first electrode 51 at the second electrode 52 side is at a position of x=3 μm; and the inner side surface of the second electrode 52 at the first electrode 51 side is at a position of x=−3 μm. The position of x=0 matches the central axis of the through-hole H.

A model a illustrates the result of a comparative example in which the first connection part 31 and the second connection part 32 were directly bonded by a metal part-metal part bond without a dielectric film interposed.

Models b to f have the configuration of the fourth embodiment above with different relative dielectric constants & of the dielectric film 90. In the model b, ε=1 (an air gap); in the model c, ε=4; in the model d, ε=8; in the model e, ε=12; and in the model f, ε=30.

According to the results of FIG. 12, as the relative dielectric constant ε of the dielectric film 90 increased, the potential ϕ approached the potential ϕ of the comparative example a that did not have a capacitively-coupled structure, and the voltage efficiency increased. For the model f in which ε=30, the potential improved to about 90% of the potential ϕ of the comparative example a. For example, a hafnium oxide film can be used as a dielectric film of which ε=30.

### Simulation 5

The time constant of a model similar to that of the simulation 4 when writing 5 V to the first electrode 51 (the deflection electrode) was estimated. The time constant is the product of the wiring resistance and the load capacitance; and it is considered that the time constant is determined by the magnitude of the load capacitance for equal wiring resistances. In FIG. 13, the vertical axis is the load capacitance, and the horizontal axis is the relative dielectric constant ε of the dielectric film 90. The model a illustrates results of the comparative example above. The model b illustrates the configuration of the fourth embodiment above with different relative dielectric constants ε of the dielectric film 90. For the fourth embodiment in the range of ε shown in FIG. 13, compared to the comparative example a, the load capacitance was less, and the write time of the deflection electrode was shorter.

The multiple first connection parts 31 and the multiple second connection parts 32 may include connection parts that contact each other at least partially without the metal parts that face each other in the first direction Z being bonded to each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An electronic device, comprising:
a first substrate including a first surface;
a second substrate including a second surface;
a wiring part located at the first surface and positioned between the first surface and the second surface in a first direction, the wiring part including a wiring layer;
a first connection part located on the wiring part, the first connection part including
a first metal part electrically connected with the wiring layer, and
a second metal part located on the second surface of the second substrate, the second metal part facing the first metal part in the first direction; and
a second connection part located on the wiring part, the second connection part including
a third metal part electrically connected with the wiring layer, and
a fourth metal part located on the second surface of the second substrate, the fourth metal part facing the third metal part in the first direction,
one of the first connection part or the second connection part having a metal part-metal part bond structure,
the other of the first connection part or the second connection part being capacitively coupled via a gap.

2. The device according to claim 1, further comprising:
a through-hole including
a first through-part extending through the first substrate in the first direction, and
a second through-part extending through the second substrate in the first direction, the second through-part being arranged with the first through-part in the first direction;
a first electrode located at an inner side surface of the second through-part, the first electrode being electrically connected with the second metal part; and
a second electrode located at the inner side surface of the second through-part, the second electrode being electrically connected with the fourth metal part.

3. The device according to claim 2, further comprising:
a first conductive film located on the second surface of the second substrate, the first conductive film being electrically connected with the first electrode and the second metal part; and
a second conductive film located on the second surface of the second substrate, the second conductive film being electrically connected with the second electrode and the fourth metal part.

4. The device according to claim 3, wherein
the second substrate is a silicon substrate, and
the device further comprises an insulating film located between the first electrode and the inner side surface of the second through-part, between the second electrode and the inner side surface of the second through-part, between the second surface and the first conductive film, and between the second surface and the second conductive film.

5. The device according to claim 2, wherein
a plurality of the through-holes, a plurality of the first connection parts, and a plurality of the second connection parts are included.

6. The device according to claim 5, wherein
the first connection parts are arranged to have a one-to-one correspondence with the through-holes, and
a number of the second connection parts is greater than a number of the first connection parts.

7. The device according to claim 1, wherein
a positive potential is applied to the first metal part,
a ground potential is applied to the third metal part,
the first metal part and the second metal part are bonded to each other, and
the third metal part and the fourth metal part are capacitively coupled via the gap.

8. The device according to claim 7, wherein
a size in the first direction of the gap between the third metal part and the fourth metal part is not more than 3 μm.

9. The device according to claim 1, wherein
the metal part-metal part bond structure is a gold-gold bond structure.

10. An electronic device, comprising:
a first chip including
a first substrate including a first surface, and
a wiring part located at the first surface, the wiring part including a wiring layer;
a second chip including a second substrate, the second substrate including a second surface facing the wiring part in a first direction; and
a connection part located between the wiring part and the second surface, the connection part being electrically connected with the wiring layer, the connection part bonding the first chip and the second chip,
the connection part including
a first metal part and a second metal part facing each other in the first direction via a gap, and
a first dielectric film located between the first metal part and the second metal part.

11. The device according to claim 10, wherein
the connection part includes a first connection part and a second connection part, mutually-different potentials are applied to the first and second connection parts,
the first connection part includes the first metal part, the second metal part, and the first dielectric film,
the second connection part includes:
a third metal part and a fourth metal part facing each other in the first direction via a gap; and
a second dielectric film located between the third metal part and the fourth metal part, and
the device further comprises:
a through-hole extending through the first substrate, the wiring part, and the second substrate in the first direction;
a first electrode located at an inner side surface of the through-hole extending through the second substrate, the first electrode being electrically connected with the first connection part; and
a second electrode located at the inner side surface of the through-hole extending through the second substrate, the second electrode being electrically connected with the second connection part.

12. The device according to claim 11, further comprising:
a first conductive film located on the second surface of the second substrate, the first conductive film being electrically connected with the first electrode and the first connection part; and
a second conductive film located on the second surface of the second substrate, the second conductive film being electrically connected with the second electrode and the second connection part.

13. The device according to claim 12, wherein
the second substrate is a silicon substrate, and
the device further comprises an insulating film located between the first electrode and the inner side surface of the through-hole, between the second electrode and the inner side surface of the through-hole, between the second surface and the first conductive film, and between the second surface and the second conductive film.

14. The device according to claim 11, wherein
a plurality of the through-holes, a plurality of the first connection parts, and a plurality of the second connection parts are included.

15. The device according to claim 14, wherein
the first connection parts are arranged to have a one-to-one correspondence with the through-holes, and
a number of the second connection parts is greater than a number of the first connection parts.

16. The device according to claim 10, wherein
the first dielectric film is a metal-oxide film.

17. The device according to claim 16, wherein
the metal-oxide film is a hafnium oxide film.
